(19) United States
(12) Patent Application Publication
(10) Pub. No.: US 2023/0318557 A1
(43) Pub. Date: Oct. 5, 2023

(54) Resonator and Preparation Method for Resonator

(71) Applicant: Wuhan MEMSonics Technologies Co., Ltd., Wuhan (CN)

(72) Inventors: Yao CAI, Wuhan (CN); Binghui LIN, Wuhan (CN); Yang ZOU, Wuhan (CN); Dawdon CHEAM, Singapore (SG); Zhipeng DING, Singapore (SG); Bowoon SOON, Singapore (SG); Chengliang SUN, Wuhan (CN)

(21) Appl. No.: 18/125,755

(22) Filed: Mar. 24, 2023

(30) Foreign Application Priority Data
Mar. 30, 2022 (CN) 202210327335.9

(51) Int. Cl. H03H 3/02; H03H 9/17

(52) U.S. Cl. CPC H03H 3/02; H03H 9/173; H03H 9/174; H03H 2003/021; H03H 2003/023

(57) ABSTRACT

The present application provides a resonator and a preparation method for a resonator, and relates to the technical field of semiconductors. The method involves introducing a first single crystal substrate to facilitate the epitaxial growth of a high-quality single crystal piezoelectric layer on the first single crystal substrate, and firstly performing ion implantation on the first single crystal substrate to form a damaged layer at a certain depth within it. Therefore, while the first single crystal substrate is removed, it is firstly possible to adopt the heating process, and after the first single crystal substrate is subjected to high-temperature treatment, a first layer and a second layer are split at the damaged layer, thereby a part of the first single crystal substrate is firstly removed, and then the remaining part of the first single crystal substrate is removed by trimming, etching, and other modes. By cooperation of two removing modes, the rapid removal of the first single crystal substrate is achieved, and the difficulty of removing the first single crystal substrate is effectively reduced.

### CROSS-REFERENCE TO RELATED APPLICATION

The present application claims priority to Chinese patent application CN202210327335.9 entitled “Resonator and Preparation Method for a Resonator” and filed on Mar. 30, 2022, and the content of which are hereby incorporated by reference in its entirety.

### TECHNICAL FIELD

The present application relates to the technical field of semiconductors, in particular to a resonator and a preparation method for a Resonator.

### BACKGROUND

With the advent of the 5G era, mobile communication systems are developed towards the goal of higher frequencies and wider frequency bands. A radio frequency filter in communication devices is the basis for receiving and transmitting signals. As a core device, the performance of the filter in the radio frequency front-end directly determines the quality of a radio frequency front-end module. The filter is composed of a plurality of resonators, so the performance of the resonators also directly determines the quality of the filter. The resonator typically includes a stacked substrate, a lower electrode layer, a piezoelectric layer, and an upper electrode layer. However, a mode of forming the lower electrode layer on the substrate may affect the growth of the subsequent piezoelectric layer due to a problem of lattice mismatch between the lower electrode layer and the substrate, so that the resonator is relatively poor in quality.

In view of the better uniformity of crystal orientation of a single crystal piezoelectric layer, existing processes introduce the single crystal piezoelectric layer to solve a problem of the low-quality piezoelectric layer in traditional deposition methods (the substrate is firstly deposited, then the lower electrode layer is deposited, and then the piezoelectric layer is deposited). In order to make the single crystal piezoelectric layer have the better quality, it is necessary to grow it on a temporary single crystal substrate, and finally the single crystal substrate needs to be removed, but also because the single crystal substrate is difficult to remove, the application of this process is limited.

### SUMMARY

A purpose of the present application is to provide a resonator and a preparation method for a resonator in response to the deficiencies of the existing technologies described above. In the process of preparing the resonator, the difficulty of removing a single crystal substrate may be improved by two times of removing processes.

In order to achieve the above purpose, technical schemes adopted by embodiments of the present application are as follows.

In one aspect of an embodiment of the present application, a preparation method for a resonator is provided, and the method includes: a first single crystal substrate is provided; a single crystal piezoelectric layer is firstly formed on the first single crystal substrate; then, ion implantation is performed on the first single crystal substrate by the single crystal piezoelectric layer to sequentially divide the first single crystal substrate into a first layer, a damaged layer located above the first layer, and a second layer located above the damaged layer and the second layer located in contact with the single crystal piezoelectric layer; a lower electrode layer is formed on the single crystal piezoelectric layer; a second substrate is formed on the lower electrode layer by a bonding process; the first layer is split from the second layer at the damaged layer by heating process; the second layer is removed to expose the single crystal piezoelectric layer; and an upper electrode layer is formed on the single crystal piezoelectric layer.

Optionally, removing the second layer to expose the single crystal piezoelectric layer includes: the second layer is removed by trimming and wet-etching.

Optionally, removing the second layer to expose the single crystal piezoelectric layer includes; the second layer is removed by trimming and dry-etching.

Optionally, the thickness ratio of the first layer to the second layer is greater than 1.

Optionally, after the upper electrode layer is formed on the single crystal piezoelectric layer, the method further includes: a first sacrificial layer is formed on the upper electrode layer; a first protective layer is formed on the first sacrificial layer, and the first protective layer covers a top wall and a side wall of the first sacrificial layer; and the first sacrificial layer is released to form a first cavity located between the first protective layer and the upper electrode layer.

Optionally, after the first sacrificial layer is released to form the first cavity located between the first protective layer and the upper electrode layer, the method further includes: a back cavity penetrating the lower electrode layer is formed on a side surface, way from the lower electrode layer, of the second substrate by etching.

Optionally, forming the second substrate on the lower electrode layer by the bonding process includes: a second sacrificial layer is formed on the lower electrode layer; a first bonding layer is formed on the second sacrificial layer; a second bonding layer is formed on the second substrate; and the first bonding layer and the second bonding layer are bonded to form the second substrate on the lower electrode layer.

Optionally, after the upper electrode layer is formed on the single crystal piezoelectric layer, the method further includes: a through hole penetrating the second sacrificial layer is formed on a side surface, away from the lower electrode layer, of the upper electrode layer by etching; a third sacrificial layer in contact with the second sacrificial layer by the through hole is formed on the upper electrode layer; a second protective layer is formed on the third sacrificial layer, and the second protective layer covers a top wall and a side wall of the third sacrificial layer; the third sacrificial layer and the second sacrificial layer are sequentially released to respectively form a second cavity located between the second protective layer and the upper electrode layer, and a third cavity located between the first bonding layer and the lower electrode layer.

Optionally, an orthographic projection of the upper electrode layer and the lower electrode layer on the single crystal piezoelectric layer has an overlapping region and a non-overlapping region, and after the upper electrode layer is formed on the single crystal piezoelectric layer, the method further includes: an extraction hole penetrating the lower electrode layer is formed on a side surface, away from the lower electrode layer, of the single crystal piezoelectric layer by etching, and the extraction hole is located in the non-overlapping region of the lower electrode layer; and an extraction electrode connected with the lower electrode layer is formed by the extraction hole.

Optionally, the first single crystal substrate is ion-implanted with single crystal ions for many times to form the damaged layer with a target thickness, as to reduce the lattice damage of the single crystal piezoelectric layer.

Optionally, an ion displacement region of the first single crystal substrate is detected, and while the ion damage degree of the ion displacement region is greater than a threshold value, the many times of the ion implantation is stopped.

Optionally, the direction of the ion implantation is consistent with the crystal axis direction of the single crystal piezoelectric layer.

Optionally, after the many times of the ion implantation is stopped, the first layer, the damaged layer, and the second layer are thermally annealed, as to reduce the damage of an ion implantation layer.

Optionally, before the single crystal piezoelectric layer is firstly formed on the first single crystal substrate, the method further includes: a groove is etched in the non-overlapping region preset on the first single crystal substrate; and

the groove is filled with a fourth sacrificial layer, so that the height of the fourth sacrificial layer is higher than the surface of the first single crystal substrate.

Optionally, before the second substrate is formed on the lower electrode layer by the bonding process, it further includes:

a bonding layer is formed between the overlapping region of the first single crystal substrate and the lower electrode layer.

Optionally, after the upper electrode layer is formed on the single crystal piezoelectric layer, it further includes:

the fourth sacrificial layer is released to generate a resonator.

In another aspect of the present application, a resonator is provided, and it is prepared by using the above preparation method for the resonator.

Optionally, a first sacrificial layer is formed on the upper electrode layer;

a first protective layer is formed on the first sacrificial layer, and the first protective layer covers a top wall and a side wall of the first sacrificial layer; and

the first sacrificial layer is released to form a first cavity located between the first protective layer and the upper electrode layer.

Optionally, a second sacrificial layer is formed on the lower electrode layer;

a first bonding layer is formed on the second sacrificial layer;

a second bonding layer is formed on the second substrate; and

the first bonding layer and the second bonding layer are bonded to form the second substrate on the lower electrode layer.

In another aspect of the present application, a resonator is provided, and it is prepared by using the above preparation method for the resonator.

The beneficial effects of the present application include:

the present application provides a resonator and a preparation method for a resonator. The method involves introducing the first single crystal substrate to facilitate the epitaxial growth of the high-quality single crystal piezoelectric layer on the first single crystal substrate, and firstly performing the ion implantation on the first single crystal substrate to form the damaged layer at a certain depth within it. Therefore, while the first single crystal substrate is removed, it is firstly possible to adopt the heating process, and after the first single crystal substrate is subjected to high-temperature treatment, the first layer and the second layer are split at the damaged layer, thereby a part of the first single crystal substrate is firstly removed, and then the remaining part of the first single crystal substrate is removed by trimming, etching, and other modes. By cooperation of two removing modes, the rapid removal of the first single crystal substrate is achieved, and the difficulty of removing the first single crystal substrate is effectively reduced.

### BRIEF DESCRIPTION OF THE DRAWINGS

In order to more clearly describe technical schemes of embodiments of the present application, drawings needed in the embodiments are briefly introduced below. It should be understood that the following drawings only illustrate some embodiments of the present application, and therefore should not be considered as limiting the scope. For those of ordinary skill in the art, other relevant drawings may also be obtained according to these drawings without creative work.

FIG. 1 is a flow schematic diagram of a preparation method for a resonator provided by an embodiment of the present application.

FIG. 2 is a first state schematic diagram of the preparation method for the resonator provided by an embodiment of the present application.

FIG. 3 is a second state schematic diagram of the preparation method for the resonator provided by an embodiment of the present application.

FIG. 4 is a third state schematic diagram of the preparation method for the resonator provided by an embodiment of the present application.

FIG. 5 is a fourth state schematic diagram of the preparation method for the resonator provided by an embodiment of the present application.

FIG. 6 is a fifth state schematic diagram of the preparation method for the resonator provided by an embodiment of the present application.

FIG. 7 is a sixth state schematic diagram of the preparation method for the resonator provided by an embodiment of the present application.

FIG. 8 is a structure schematic diagram of a resonator provided by an embodiment of the present application.

FIG. 9 is a first state schematic diagram of the preparation method for the resonator provided by another embodiment of the present application.

FIG. 10 is a second state schematic diagram of the preparation method for the resonator provided by another embodiment of the present application.

FIG. 11 is a third state schematic diagram of the preparation method for the resonator provided by another embodiment of the present application.

FIG. 12 is a fourth state schematic diagram of the preparation method for the resonator provided by another embodiment of the present application.

FIG. 13 is a fifth state schematic diagram of the preparation method for the resonator provided by another embodiment of the present application.

FIG. 14 is a sixth state schematic diagram of the preparation method for the resonator provided by another embodiment of the present application.

FIG. 15 is a structure schematic diagram of a resonator provided by another embodiment of the present application.

FIG. 16 is a seventh state schematic diagram of the preparation method for the resonator provided by another embodiment of the present application.

FIG. 17 is an eighth state schematic diagram of the preparation method for the resonator provided by another embodiment of the present application.

FIG. 18 is a ninth state schematic diagram of the preparation method for the resonator provided by another embodiment of the present application.

FIG. 19 is a tenth state schematic diagram of the preparation method for the resonator provided by another embodiment of the present application.

FIG. 20 is an eleventh state schematic diagram of the preparation method for the resonator provided by another embodiment of the present application.

FIG. 21 is a twelfth state schematic diagram of the preparation method for the resonator provided by another embodiment of the present application.

FIG. 22 is a thirteenth state schematic diagram of the preparation method for the resonator provided by another embodiment of the present application.

FIG. 23 is a fourteenth state schematic diagram of the preparation method for the resonator provided by another embodiment of the present application.

### DETAILED DESCRIPTION OF THE EMBODIMENTS

Implementation modes stated below represent the information necessary for those skilled in the art to practice the implementation modes, and show the best mode to practice the implementation modes. After reading the following description with reference to the drawings, those skilled in the art may understand the concepts of the present disclosure, and may recognize applications of these concepts that are not specifically proposed herein. It is to be understood that these concepts and applications fall within the scope of the present disclosure and the attached claims.

It is to be understood that, the terms first, second, etc. may be configured herein to describe various elements, but these elements should not be limited to these terms. These terms are only configured to distinguish one element from another. For example, without departing from the scope of the present disclosure, a first element may be referred to as a second element, and similarly, the second element may also be referred to as the first element. As used herein, the term “and/or” used herein includes any and all combinations of one or more of the associated listed items.

It is to be understood that when an element (such as a layer, an area, or a substrate) is referred to as “being on another element” or “extending to another element”, it may be directly on another element or directly extend to another element, or there may be an element therebetween. On the contrary, when on element is referred to as “being directly on another element” or “directly extending to another element”, there is no element therebetween. Similarly, it is to be understood that when an element (such as a layer, an area, or a substrate) is referred to as “being on another element” or “extending on another element”, it may be directly on another element or directly extend on another element, or there may be an element therebetween. On the contrary, when an element is referred to as “being directly on another element” or “directly extending on another element”, there is no element therebetween. It is also understood that when an element is referred to as being “connected” or “coupled” to another element, it may be directly connected or coupled to another element, or there is an element therebetween. On the contrary, when an element is referred to as being “directly connected” or “directly coupled” to another element, there is no element therebetween.

Related terms such as “below” or “above” or “upper” or “lower” or “horizontal” or “vertical” may be configured herein to describe the relationship between one element, layer, or area and another element, layer, or area, as shown in the drawings. It is to be understood that these terms and those discussed above are intended to cover different orientations of an apparatus other than those depicted in the drawings.

The terms used herein are only used for the purpose of illustrating specific implementation modes, and are not intended to limit the present disclosure. As used herein, singular forms “a”, “an”, and “the” are also intended to include plural forms as well, unless the context explicitly otherwise. It is also to be understood that, when used herein, the term “including” indicates the existence of the features, integers, steps, operations, elements, and/or components, but does not exclude the existence or addition of one or more other features, integers, steps, operations, elements, components, and/or groups of the foregoing.

Unless otherwise defined, all terms used herein (including technical terms and scientific terms) have the same meanings as those commonly understood by those of ordinary in the art of the invention. It is also to be understood that the terms used herein shall be interpreted as having the same meaning as they have in the description and related fields, and shall not be interpreted in an idealized or overly formal sense, unless they have been explicitly defined herein.

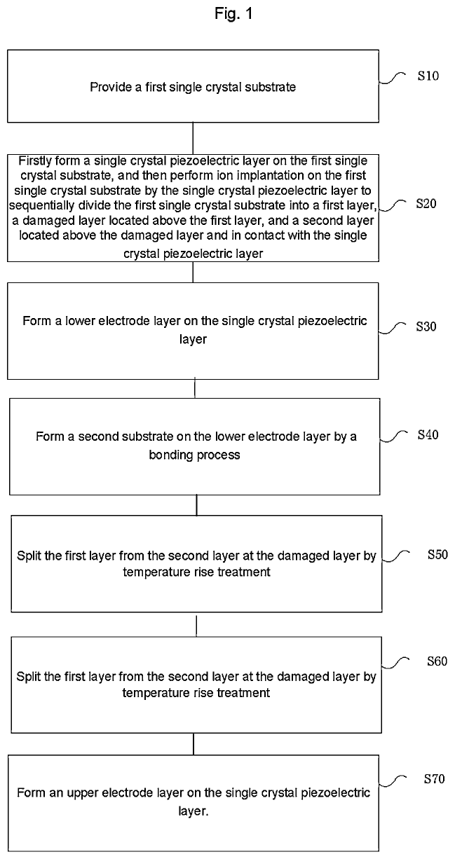

In one aspect of an embodiment of the present application, a preparation method for a resonator is provided, as shown in FIG. 1, the method includes:

S010: a first single crystal substrate is provided.

S020: a single crystal piezoelectric layer is firstly formed on the first single crystal substrate; then, ion implantation is performed on the first single crystal substrate by the single crystal piezoelectric layer to sequentially divide the first single crystal substrate into a first layer, a damaged layer located above the first layer, and a second layer located above the damaged layer and in contact with the single crystal piezoelectric layer.

S030: a lower electrode layer is formed on the single crystal piezoelectric layer.

S040: a second substrate is formed on the lower electrode layer by a bonding process.

S050: the first layer is split from the second layer at the damaged layer by heating process.

S060: the second layer is removed to expose the single crystal piezoelectric layer.

S070: an upper electrode layer is formed on the single crystal piezoelectric layer.

The first single crystal substrate is introduced to facilitate the epitaxial growth of the high-quality single crystal piezoelectric layer on the first single crystal substrate, and firstly the ion implantation is performed on the first single crystal substrate to form the damaged layer at a certain depth within it. Therefore, while the first single crystal substrate is removed, it is firstly possible to adopt the heating process, and after the first single crystal substrate is subjected to high-temperature treatment, the first layer and the second layer are split at the damaged layer, thereby a part of the first single crystal substrate is firstly removed, and then the remaining part of the first single crystal substrate is removed by trimming, etching, and other modes. By cooperation of two removing modes, the rapid removal of the first single crystal substrate is achieved, and the difficulty of removing the first single crystal substrate is effectively reduced.

On the basis of the above effects, on the one hand, the lower electrode and the upper electrode of the present application are both directly formed on the single crystal piezoelectric layer, so that a problem of lattice mismatch between the electrode and the substrate may be avoided.

On the other hand, it is considered that the formation of the single crystal piezoelectric layer is in a high-temperature environment, the present application allows the formation step of the single crystal piezoelectric layer to precede the formation steps of the lower electrode and the upper electrode. In this way, the high-temperature environment in which the single crystal piezoelectric layer is prepared may be avoided to cause adverse effects such as oxidation on the already formed lower electrode and upper electrode, thereby the quality of the resonator prepared by the present application is effectively guaranteed.

On the other hand, it is also considered that the formation of the single crystal piezoelectric layer is in the high-temperature environment, the present application allows the formation step of the single crystal piezoelectric layer to precede the formation step of the damaged layer by the ion implantation process. Therefore, it is possible to avoid premature splitting of the first single crystal substrate that already has the damaged layer due to the high-temperature environment in which the single crystal piezoelectric layer is formed, and the adverse effects on the preparation of the resonator are avoided.

On the other hand, since the first layer of the first single crystal substrate is split from the second layer of the first single crystal substrate under high-temperature treatment, the split first layer may also be recycled and reused.

In some implementation modes, the thickness ratio of the first layer to the second layer is greater than 1. In other words, the thickness of the first layer is greater than the thickness of the second layer. Therefore, by splitting, it is possible to firstly remove more parts of the first single crystal substrate, thus more parts of the first single crystal substrate are allowed to be reused, while the rate of removing the first single crystal substrate may also be further improved.

In order to further describe the preparation method for the resonator of the present application, it is described below in the form of embodiments in combination with drawings.

In one implementation mode:

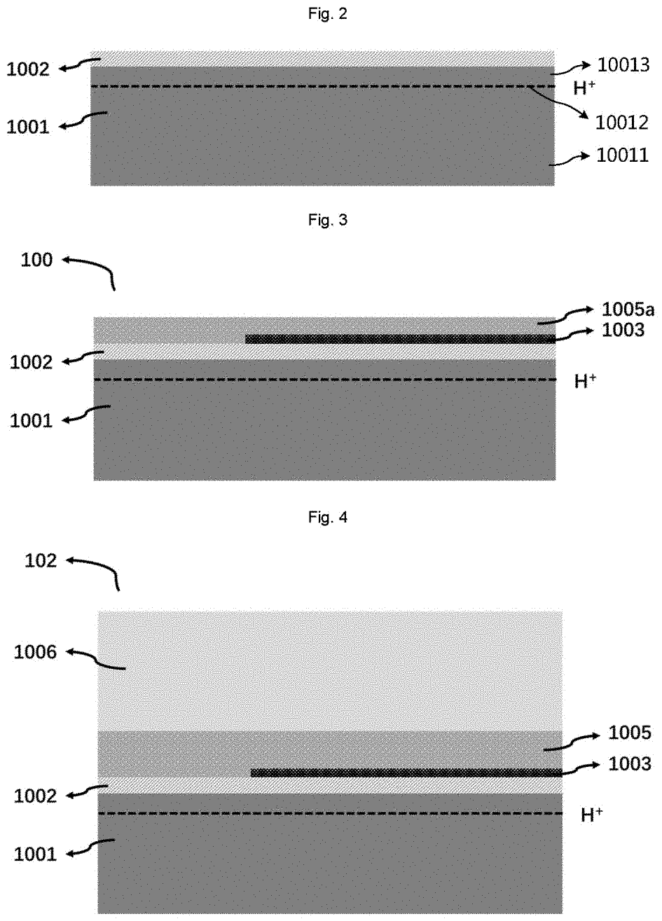

Referring to FIG. 2, a first single crystal substrate 1001 is provided, to facilitate the subsequent epitaxial growth of a single crystal piezoelectric layer 1002. The first single crystal substrate 1001 may be a SiC substrate, a GaN substrate, a Si substrate, a sapphire substrate and the like. The present application does not limit it, and reasonable choices may be made according to actual needs.

Please continue to refer to FIG. 2, the epitaxial growth of the single crystal piezoelectric layer 1002 is firstly performed on the upper surface of the first single crystal substrate 1001. Due to the lattice compatibility of the two, the single crystal piezoelectric layer 1002 has the better quality. The material of the single crystal piezoelectric layer 1002 may be AlN. The temperature at which the single crystal piezoelectric layer 1002 is grown is 900 to 1200° C.

After the single crystal piezoelectric layer 1002 is formed on the upper surface of the first single crystal substrate 1001, the ion implantation is performed into the first single crystal substrate 1001 by the upper surface of the single crystal piezoelectric layer 1002, thereby a damaged layer 10012 is formed at a certain depth of the first single crystal substrate 1001. The first single crystal substrate 1001 is divided into two parts by the damaged layer 10012, and the three forms a first layer 10011, the damage layer 10012, and a second layer 10013 that are sequentially stacked, herein the second layer 10013 is adjacent to the single crystal piezoelectric layer 1002, and is in contact with the single crystal piezoelectric layer 1002. The ions implanted may be H⁺, the implanted energy is greater than 1 MeV, and the implanted dose may range from 9E15/cm² to 7E17/cm².

Please refer to FIG. 3, a metal is then deposited on the upper surface of the single crystal piezoelectric layer 1002, and the metal is patterned to form a lower electrode layer 1003. The material of the lower electrode layer 1003 may be Mo.

Please continue to refer to FIG. 3, after the lower electrode layer 1003 is formed on the upper surface of the single crystal piezoelectric layer 1002, a first bonding layer 1005a is continued to be deposited on the lower electrode layer 1003, to obtain a device wafer 100.

Please refer to FIG. 4, a second substrate 1006 is provided, and the material of the second substrate 1006 may be a high resistance silicon. Then, a second bonding layer is formed by depositing on the surface of one side of the second substrate 1006, to obtain a cap wafer. A bonding technology is used to bond the first bonding layer 1005a and the second bonding layer so as to form a bonding layer 1005, namely the cap wafer and the device wafer 100 are bonded to form a composite wafer 102.

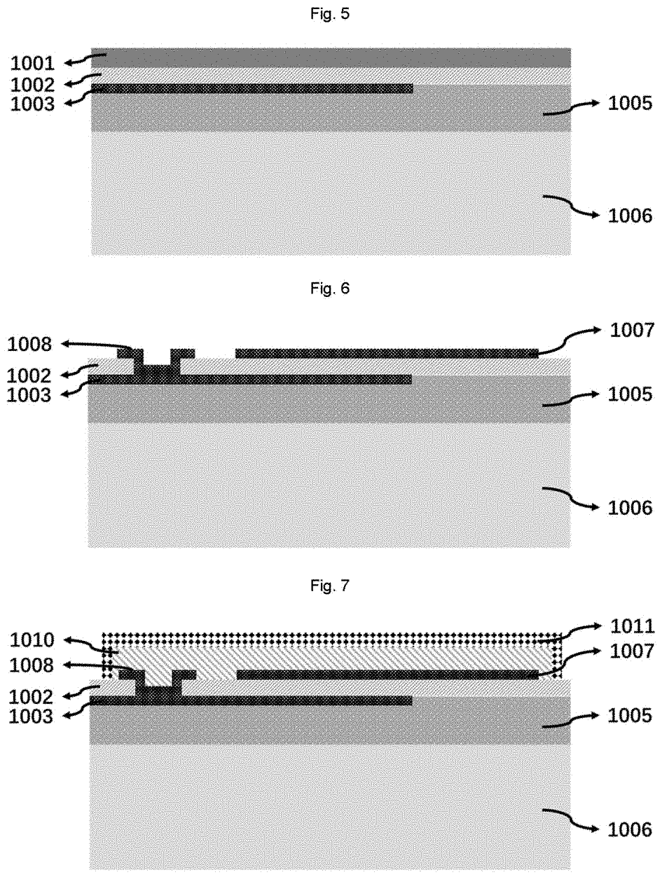

Please refer to FIG. 5, the composite wafer 102 is inverted, and subjected to high-temperature treatment, so that the first layer 10011 is split from the second layer 10013 at the damaged layer 10012, thereby the first layer 10011 is removed from the composite wafer 102.

Please refer to FIG. 6, the remaining first single crystal substrate 1001 is then removed by a mode of trimming+dry-etching or trimming+wet-etching, to expose the upper surface of the single crystal piezoelectric layer 1002. The cooperation of two processes of trimming+etching may improve the removal rate, shorten the removal cycle, and facilitate the mass production.

Please continue to refer to FIG. 6, after the upper surface of the single crystal piezoelectric layer 1002 is exposed, the single crystal piezoelectric layer 1002 is etched, thereby an extraction hole penetrating the lower electrode layer 1003 is formed on the upper surface of the single crystal piezoelectric layer 1002. A metal is deposited on the upper surface of the single crystal piezoelectric layer 1002, and the deposited metal is patterned to form two mutually separated parts. One part serves as the upper electrode layer 1007, and the other part is located in the extraction hole and the periphery of the extraction hole serves as an extraction electrode 1008. The extraction electrode 1008 is connected with the lower electrode layer 1003 by the extraction hole, and it is achieved that the lower electrode layer 1003 is extracted to the upper surface of the single crystal piezoelectric layer 1002 for subsequent packaging and external connection. It should be noted that the orthographic projections of the upper electrode layer 1007 and the lower electrode layer 1003 on the single crystal piezoelectric layer 1002 each have an overlapping region and a non-overlapping region, and the overlapping region of the two serves as an effective working region of the resonator. For the upper electrode layer 1007, it includes two parts, one part is located in the overlapping region, and the other part is located in the non-overlapping region; and for the lower electrode layer 1003, it also includes two parts, one part is located in the overlapping region, and the other part is located in the non-overlapping region. The setting position of the extraction hole is located in the non-overlapping region of the lower electrode layer 1003, as to avoid contact between the lower electrode layer 1003 and the upper electrode layer 1007.

Please refer to FIG. 7, a first sacrificial layer 1010 is firstly formed by depositing on the upper electrode layer 1007, and the first sacrificial layer 1010 should at least cover the effective working region of the resonator.

Please continue to refer to FIG. 7, a first protective layer 1011 is then deposited on the first sacrificial layer 1010, and the first protective layer 1011 covers a top wall and all side walls (peripheral wall) of the first sacrificial layer.

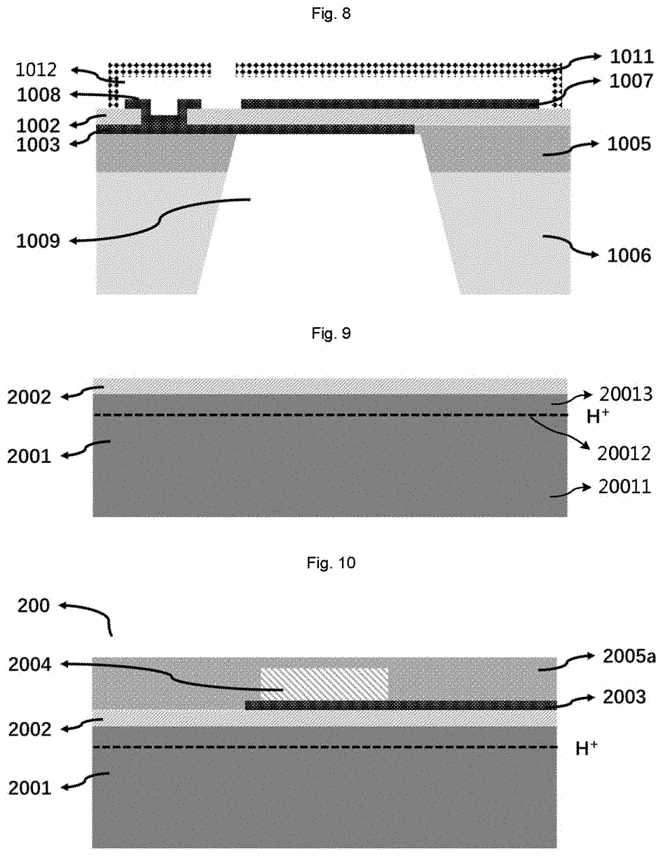

Please refer to FIG. 8, a releasing hole penetrating the first sacrificial layer 1010 is formed on the first protective layer 1011 by etching. By sequentially etching the second substrate 1006 and the bonding layer 1005, a back cavity 1009 communicated to the lower surface of the lower electrode layer 1003 is formed, and the back cavity 1009 should be covered by the effective working region. The first sacrificial layer 1010 is released by the releasing hole, thus a first cavity 1012 is formed between the first protective layer 1011 and the upper electrode layer 1007. The first protective layer 1011 may protect the structure inside the first cavity 1012, and a side wall of the first protective layer 1011 may also form an acoustic reflection structure, thereby acoustic wave leakage may be reduced, and the performance of the resonator is improved.

In another implementation mode:

Referring to FIG. 9, a first single crystal substrate 2001 is provided, to facilitate the subsequent epitaxial growth of a single crystal piezoelectric layer 2002. The first single crystal substrate 2001 may be a SiC substrate, a GaN substrate, a Si substrate, a sapphire substrate and the like. The present application does not limit it, and reasonable choices may be made according to actual needs.

Please continue to refer to FIG. 9, the epitaxial growth of the single crystal piezoelectric layer 2002 is firstly performed on the upper surface of the first single crystal substrate 2001. Due to the lattice compatibility of the two, the single crystal piezoelectric layer 2002 has the better quality. The material of the single crystal piezoelectric layer 2002 may be AlN. The temperature at which the single crystal piezoelectric layer 2002 is grown is 900 to 1200° C.

After the single crystal piezoelectric layer 2002 is formed on the upper surface of the first single crystal substrate 2001, the ion implantation is performed into the first single crystal substrate 2001 by the upper surface of the single crystal piezoelectric layer 2002, thereby a damaged layer 20012 is formed at a certain depth of the first single crystal substrate 2001. The first single crystal substrate 2001 is divided into two parts by the damaged layer 20012, and the three forms a first layer 20011, the damage layer 20012, and a second layer 20013 that are sequentially stacked, herein the second layer 20013 is adjacent to the single crystal piezoelectric layer 2002, and is in contact with the single crystal piezoelectric layer 2002. The ions implanted may be H⁺, the implanted energy is greater than 1 MeV, and the implanted dose may range from 9E15/cm² to 7E17/cm².

Please refer to FIG. 10, a metal is then deposited on the upper surface of the single crystal piezoelectric layer 2002, and the metal is patterned to form a lower electrode layer 2003. The material of the lower electrode layer 2003 may be Mo.

Please continue to refer to FIG. 10, after the lower electrode layer 2003 is formed on the upper surface of the single crystal piezoelectric layer 2002, a second sacrificial layer 2004 is firstly deposited on the lower electrode layer. It should be understood that the second sacrificial layer 2004 is located in the effective working region, then a first bonding layer 2005a covering the second sacrificial layer 2004 is deposited on the lower electrode layer 2003, and grinding the upper surface of the first bonding layer 2005a, to obtain a relatively flat surface, thereby a device wafer 200 is obtained.

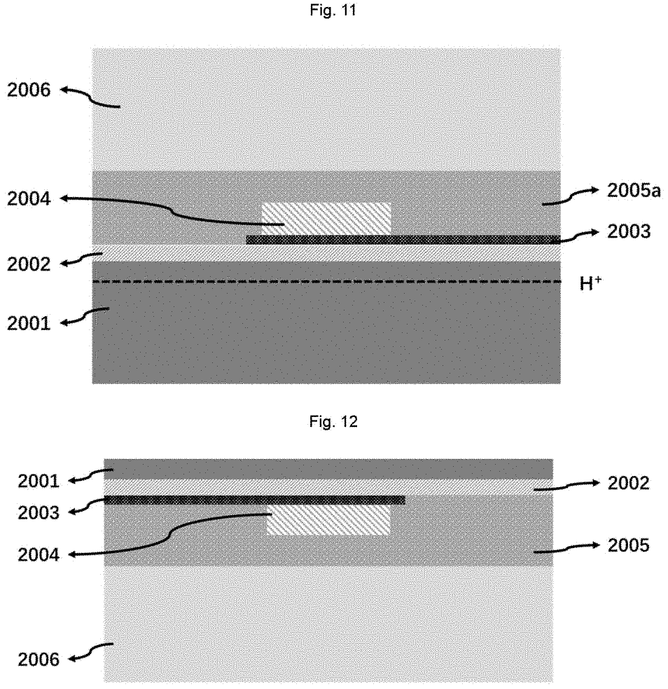

Please refer to FIG. 11, a second substrate 2006 is provided, and the material of the second substrate 2006 may be a high resistance silicon. Then, a second bonding layer is formed by depositing on the surface of one side of the second substrate 2006, to obtain a cap wafer. A bonding technology is used to bond the first bonding layer 2005a and the second bonding layer so as to form a bonding layer 2005, namely the cap wafer and the device wafer 200 are bonded to form a composite wafer 202.

Please refer to FIG. 12, the composite wafer 202 is inverted, and subjected to high-temperature treatment, so that the first layer 20011 is split from the second layer 20013 at the damaged layer 20012, thereby the first layer 20011 is removed from the composite wafer 202.

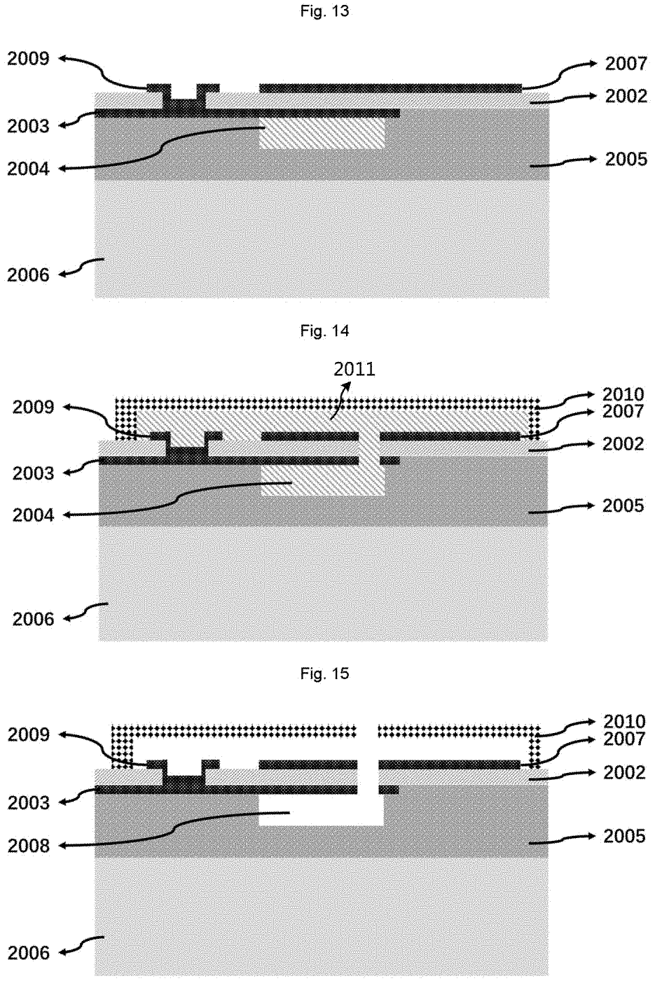

Please refer to FIG. 13, the remaining first single crystal substrate 2001 is then removed by a mode of trimming+dry-etching or trimming+wet-etching, to expose the upper surface of the single crystal piezoelectric layer 2002. The cooperation of two processes of trimming+etching may improve the removal rate, shorten the removal cycle, and facilitate the mass production.

Please continue to refer to FIG. 13, after the upper surface of the single crystal piezoelectric layer 2002 is exposed, the single crystal piezoelectric layer 2002 is etched, thereby an extraction hole penetrating the lower electrode layer 2003 is formed on the upper surface of the single crystal piezoelectric layer 2002. A metal is deposited on the upper surface of the single crystal piezoelectric layer 2002, and the deposited metal is patterned to form two mutually separated parts. One part serves as the upper electrode layer 2007, and the other part is located in the extraction hole and the periphery of the extraction hole serves as an extraction electrode 2009. The extraction electrode 2009 is connected with the lower electrode layer 2003 by the extraction hole, and it is achieved that the lower electrode layer 2003 is extracted to the upper surface of the single crystal piezoelectric layer 2002 for subsequent packaging and external connection. It should be noted that the orthographic projections of the upper electrode layer 2007 and the lower electrode layer 2003 on the single crystal piezoelectric layer 2002 each have an overlapping region and a non-overlapping region, and the overlapping region of the two serves as an effective working region of the resonator. For the upper electrode layer 2007, it includes two parts, one part is located in the overlapping region, and the other part is located in the non-overlapping region; and for the lower electrode layer 2003, it also includes two parts, one part is located in the overlapping region, and the other part is located in the non-overlapping region. The setting position of the extraction hole is located in the non-overlapping region of the lower electrode layer 2003, as to avoid contact between the lower electrode layer 2003 and the upper electrode layer 2007.

Please refer to FIG. 14, the upper electrode layer 2007, the single crystal piezoelectric layer 2002, and the lower electrode layer 2003 are sequentially etched to form a through hole, and the through hole is communicated to the surface surface of the second sacrificial layer 2004. Then, a third sacrificial layer 2011 is formed by depositing on the upper electrode layer 2007, the third sacrificial layer 2011 should at least cover the effective working region of the resonator, and at the same time, the third sacrificial layer 2011 is also in contact with the second sacrificial layer 2004 by the through hole.

Please continue to refer to FIG. 14, a second protective layer 2010 is then deposited on the third sacrificial layer 2011, and the second protective layer 2010 covers a top wall and all side walls (peripheral wall) of the third sacrificial layer.

Please refer to FIG. 15, a releasing hole penetrating the third sacrificial layer 2011 is formed on the second protective layer 2010 by etching. The third sacrificial layer 2011 may be sequentially released by the releasing hole and the through hole, and then the second sacrificial layer 2004 is released. Therefore, a second cavity is formed between the second protective layer 2010 and the upper electrode layer 2007, and a third cavity 2008 is formed between the bonding layer 2005 and the lower electrode layer 2003. The second protective layer 2010 may protect the structure inside the second cavity, and a side wall of the second protective layer 2010 may also form an acoustic reflection structure, thereby acoustic wave leakage may be reduced, and the performance of the resonator is improved.

As shown in FIGS. 8 to 12, the first single crystal substrate 2001 is ion-implanted with single crystal ions for many times to form the damaged layer 20012 with a target thickness, as to reduce the lattice damage of the single crystal piezoelectric layer 2002. The depth of ion implantation is estimated by a simulation method, and the position of the damaged layer is calculated by providing ion dose, range, and implantation angle. The ion implantation may be performed again after one time of the ion implantation, and the number of times is not limited. The conditions and modes of the ion implantation may be adopted but not limited, and may be determined according to demands. The types of the ion implantation may be helium (He), hydrogen (H), krypton (Kr), xenon (Xe), boron (B), phosphorus (P), arsenic (As), or antimony (Sb). The low implantation energy range is 2 keV-400 keV, the high implantation energy range is 450 keV-10 MeV, the low implantation dose is 1*1015/cm²-8*1015/cm², and the high implantation dose is 1*1012/cm²-8*1018/cm². The implantation angle is within the range of 0-60°. The position and thickness of the damaged layer 20012 may be evaluated by using a principle of optical exploration and detection of an interface without damaging the first single crystal substrate 2001, or the crack section analysis of the same batch of wafers may be performed under the condition of damaging the wafers, to accurately obtain the thickness information of the damaged layer. forming the damaged layer 20012 with the preset depth in the first single crystal substrate 2001 includes:

S1: a photoresist is spin-coated the single crystal piezoelectric layer 2002 and a first implantation window is formed by etching, and the first implantation window is overlapped with the projection of the first cavity 1012 on the first single crystal substrate 2001.

It may be seen from the above that, the damaged layer 20012 occupies a part of the preset depth in the first single crystal substrate 2001, the photoresist is spin-coated and etched to form the first implantation window. the first implantation window serves as a selected region window for first ion implantation, and in the first ion implantation process, only high-energy ions directed towards the first implantation window may enter the preset depth in the first single crystal substrate 2001.

S2: by the first implantation window, the first ion implantation is performed at the preset depth of the first single crystal substrate 2001 to form the damaged layer 20012 with the preset thickness, herein the first ion implantation includes many times of ion implantation, and the implantation centers of the many times of the ion implantation are not at the same depth.

An ion replacement region of the first single crystal substrate 2001 is detected, and while the ion damage degree in the ion replacement region is greater than a threshold value, the many times of the ion implantation is stopped. Since the damaged layer 20012 has a certain thickness, during the first ion implantation, due to the normal distribution of ions within the thickness range of the first single crystal substrate 2001 after the ion implantation, the depth at which different ion implantation doses enter the first single crystal substrate 2001 varies. The dose during the ion implantation may be changed by the many times of the ion implantation, and the damaged layer 20012 formed after each time of the ion implantation may be overlapped, and eventually, a larger damage range is formed. After the damaged layer 20012 is formed by the many times of the ion implantation, the damaged layer 20012 with the preset thickness may be formed.

It should be noted that the first ion implantation includes many times of ion implantation, and the implantation centers of the many times of the ion implantation are not at the same depth. Here, they are not at the same depth, and the implantation centers of the many times of the ion implantation are all within the thickness range of the damaged layer 20012.

In addition, in order to prevent the lattice structure of the single crystal piezoelectric layer 2002 from being damaged by the high-energy ions striking the single crystal piezoelectric layer 2002 during the ion implantation of the first ion implantation, before the photoresist is spin-coated the single crystal piezoelectric layer 2002, a barrier layer may be arranged on the single crystal piezoelectric layer 2002 to protect the surface of the single crystal piezoelectric layer 2002.

In an achievable mode of an embodiment of the present application, the first single crystal substrate 2001 is a single crystal substrate, and the single crystal piezoelectric layer 2002 is a single crystal piezoelectric thin film layer.

The first single crystal substrate 2001 is the single crystal substrate, it has a regular lattice structure, and may provide the regular lattice structure for the single crystal piezoelectric thin film layer. During subsequent preparation of the piezoelectric thin film layer, a single crystal piezoelectric thin film may be formed, thereby the lattice regularity of the piezoelectric thin film layer is improved, and the thin film quality of the single crystal piezoelectric layer 2002 is further improved, thus the performance of a bulk acoustic wave resonator is improved.

As shown in FIGS. 9 to 15, forming the lower electrode layer 2003 on the other side of the single crystal piezoelectric layer 2002 by second ion implantation includes:

S3: a photoresist is spin-coated the upper electrode layer 2007 and a second implantation window is formed, the second implantation window is coincided with the first implantation window.

Similar to the setting of the first implantation window, the second implantation window serves as a selected region window for the second ion implantation.

S4: the substrate material on the other side of the single crystal piezoelectric layer 2002 is doped by the second implantation window.

In an achievable mode of an embodiment of the present application, the implantation energy of the second ion implantation is smaller than the implantation energy of the first ion implantation, and the implantation dose of the second ion implantation is smaller than the implantation dose of the first ion implantation.

It may be seen from the above that, the first ion implantation forms the damaged layer 20012, the second ion implantation forms the lower electrode layer 2003, and the damaged layer 20012 is located below the lower electrode layer 2003, so that the first ion implantation has a deeper implantation depth, and therefore, the implantation energy of the first ion implantation is larger, so the ions are allowed to enter the deeper depth, and the damaged layer 20012 is formed. In addition, the damaged layer 20012 is used to form the first cavity 1012 after etching. During etching, in order to make the composition difference between the damaged layer 20012 and the surrounding substrate material larger, and facilitate the etching, the implantation dose of the first ion implantation should be set to be larger; and the second ion implantation involves doping impurities into the substrate to change the conductivity of the substrate material and make it serve as the lower electrode layer 2003 of the bulk acoustic wave resonator 10. Therefore, the implantation dose for the second ion implantation is set to be smaller.

Herein, due to the larger implantation depth during the first ion implantation, while the implantation energy is adjusted to achieve a certain depth of the ion implantation, it may also be performed by setting smaller ions. For example, the ions with the smaller atomic numbers such as helium, hydrogen, krypton, xenon, magnesium, fluorine, oxygen, copper, or gold may be selected as the implantation ions for the first ion implantation, because the ions with the smaller atomic numbers have the smaller collision cross sections, and are able to enter deeper positions. Similarly, the ions with the larger atomic numbers may be set as implanted ions for the second ion implantation. For example, boron, phosphorus, arsenic, or antimony may be selected.

Optionally, the implantation energy of the first ion implantation is between 450 keV-10 MeV, the implantation dose is between 1*1012-8*1018/cm², and the implantation thickness is between 80-200 nm; the implantation energy of the second ion implantation is between 2-400 keV, and the implantation dose is between 1*1015-8*1015/cm².

While the first single crystal substrate 2001 in an embodiment of the present application is a silicon substrate, the implanted ion for the first ion implantation is helium, and the implanted ion for the second ion implantation is boron, the implantation energy for the first ion implantation is between 450 keV-10 MeV, the implantation dose is between 1*1012-8*1018/cm², and the implantation thickness is between 80-200 nm; and the implantation energy of the second ion implantation is between 2-400 keV, and the implantation dose is between 1*1015-8*1015/cm².

As shown in FIGS. 2 to 6, in an achievable mode of an embodiment of the present application, after the substrate material on the other side of the single crystal piezoelectric layer 2002 is doped by the second implantation window, the preparation method for the resonator further includes: after the many times of the ion implantation is stopped, the first layer 10011, the damaged layer 20012, and the second layer 10013 are thermally annealed, as to reduce the damage of the ion implantation layer.

S5: the doped first single crystal substrate 2001 is annealed at an annealing temperature between 600-1200° C.

It should be known by those skilled in the art that the ion implantation is to accelerate impurity ions and make the impurity ions with the large kinetic energy obtained enter the first single crystal substrate 2001. In this process, due to the large kinetic energy of the impurity ions entering the first single crystal substrate 2001, the damage to the lattice of the first single crystal substrate 2001 may be produced, and the impurity ions do not enter the lattice. In order to repair the damage to the lattice, the impurity ions enter the lattice to change the electrical resistivity of the lower electrode layer 2003. After the second ion implantation, the doped first single crystal substrate 2001 is annealed. The specific annealing conditions are not limited in the embodiments of the present application, as long as it is possible to redistribute the doped ions into the substrate while the lattice damage is repaired. For example, the annealing temperature may be set at 600-1200° C., and the annealing gas is an inert gas.

Optionally, forming the upper electrode layer 2007 on one side of the single crystal piezoelectric layer 2002 includes:

S31: a metal material is spin-coated the single crystal piezoelectric layer 2002 to form a metal layer.

S32: the metal layer is patterned to form the upper electrode layer 2007.

The metal layer is patterned so that the upper electrode layer 2007 form different shapes on the single crystal piezoelectric layer 2002. In this way, a step-like structure is formed between the edges of the single crystal piezoelectric layer 2002 and the upper electrode layer 2007, and the step-like structure forms a phononic crystal structure, thereby an acoustic wave generated by the single crystal piezoelectric layer 2002 may be inhibited to be propagated into the upper electrode layer 2007, and the parasitic mode of the bulk acoustic wave resonator 10 is reduced.

Herein, the specifically patterned patterns in the embodiments of the present application are not limited. For example, it may be a quadrangle, a pentagon, a rhombus, an ellipse, a circle, or other shapes.

In an achievable mode of an embodiment of the present application, releasing the damaged layer 20012 to form the first cavity 1012 includes:

S41: a releasing hole is formed on the single crystal piezoelectric layer 2002 and the first single crystal substrate 2001.

S42: etching solution is implanted by the releasing hole, and the damaged layer 20012 is etched by the etching solution to form the first cavity 1012.

Some materials in the first single crystal substrate 2001 are changed by the first ion implantation, and the etching solution of which the etching rate for the damaged layer 20012 is relatively high, but the etching rate for the material of the first single crystal substrate 2001 is relatively low or non-etched is adopted. The etching solution is in contact with the damaged layer 20012 by the releasing hole, and the damaged layer 20012 is etched. After the etching is completed, the first cavity 1012 may be formed by cleaning the etching solution and residual particles of the material.

The direction of the ion implantation is consistent with the crystal axis direction of the single crystal piezoelectric layer 2002. By detecting the crystal axis direction of the single crystal piezoelectric layer to be implanted, the angle between an ion implanter and the wafer may be adjusted to ensure that the direction of the ion implantation is consistent with the crystal axis direction of the single crystal piezoelectric layer 2002.

As shown in FIGS. 7 to 10, a resonator provided by an embodiment of the present application is prepared by using the above preparation method for the resonator.

Specifically, a first sacrificial layer 1010 is formed on the upper electrode layer 1007.

A first protective layer 1011 is formed on the first sacrificial layer 1010, and the first protective layer 1011 covers a top wall and a side wall of the first sacrificial layer 1010.

The first sacrificial layer 1010 is released to form a first cavity located between the first protective layer 1011 and the upper electrode layer 1007.

A second sacrificial layer 2004 is formed on the lower electrode layer 2003.

A first bonding layer 2005a is formed on the second sacrificial layer 2004.

A second bonding layer is formed on the second substrate 2006.

The first bonding layer 2005a and the second bonding layer are bonded to form the second substrate 2006 on the lower electrode layer 2003.

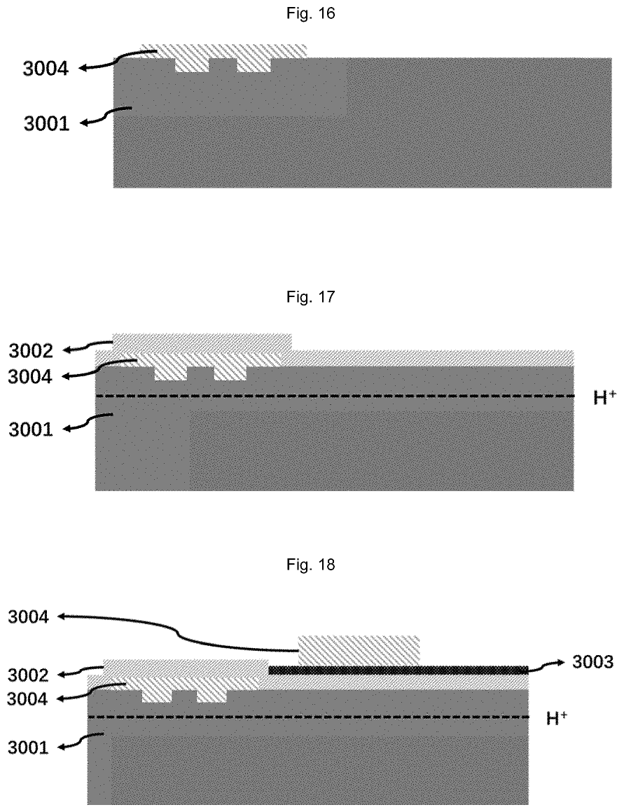

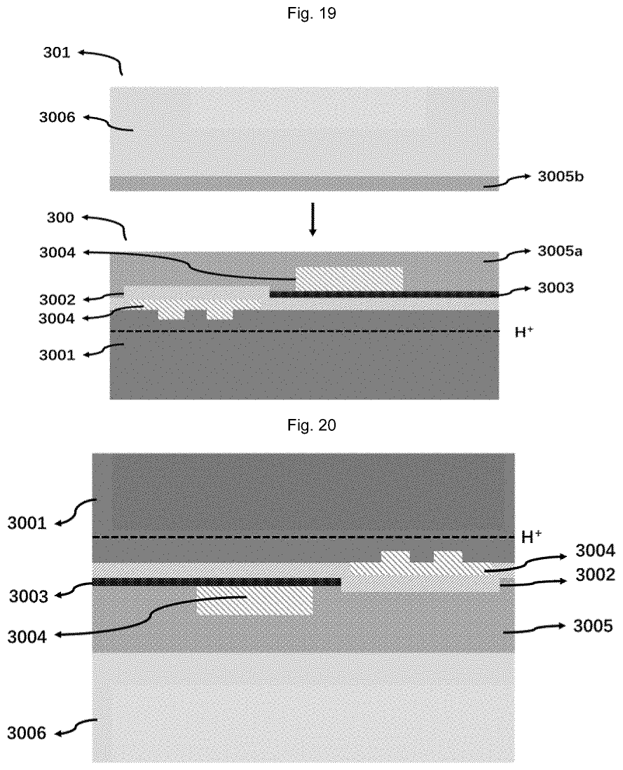

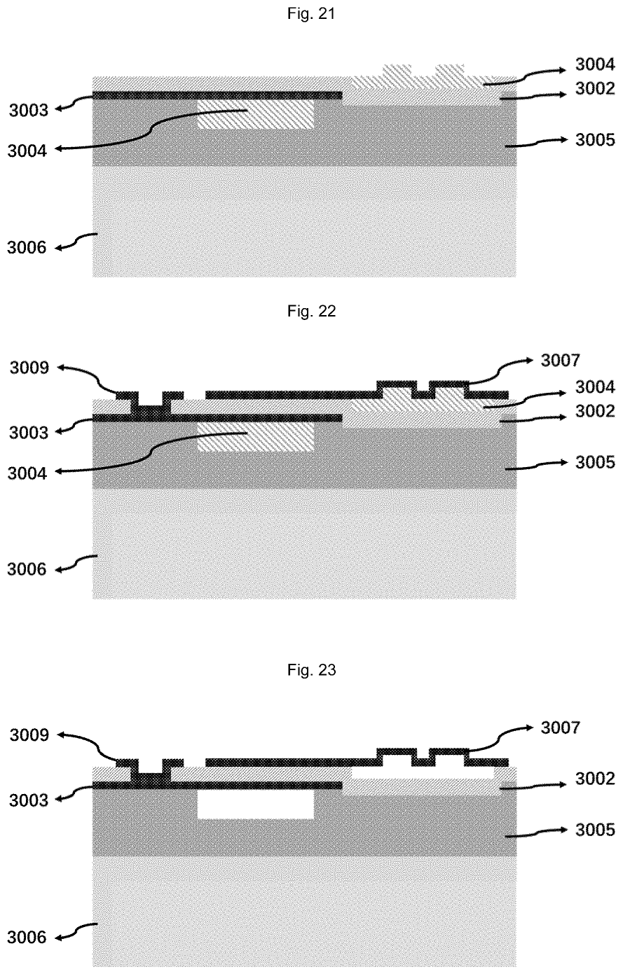

As shown in FIGS. 16 to 23, before the single crystal piezoelectric layer 3002 is firstly formed on the first single crystal substrate 3001, it further includes: a groove is etched in the non-overlapping region preset on the first single crystal substrate 3001.

The groove is filled with a fourth sacrificial layer 3004, so that the height of the fourth sacrificial layer 3004 is higher than the surface of the first single crystal substrate 3001.

Before the second substrate 3006 is formed on the lower electrode layer 3003 by the bonding process, it further includes:

a bonding layer is formed between the overlapping region of the first single crystal substrate 3001 and the lower electrode layer 3003, and the bonding layer includes a first bonding layer 3005a and a second bonding layer 3005b.

After the upper electrode layer 3007 is formed on the single crystal piezoelectric layer 3002, it further includes:

the fourth sacrificial layer 3004 is released to generate a resonator.

In another aspect of an embodiment of the present application, a resonator is provided, and it is prepared by using any one of the above preparation methods for the resonator, so that the resonator prepared has the higher quality and performance.

The above are only preferred embodiments of the present application, and are not intended to limit the present application. For those skilled in the art, the present application may have various modifications and changes. Any modifications, equivalent replacements, improvements and the like made within the spirit and principles of the present application shall be included in the scope of protection of the present application.

What is claimed is:

1. A preparation method for a resonator, wherein the method comprises:
providing a first single crystal substrate;
firstly forming a single crystal piezoelectric layer on the first single crystal substrate, and then performing ion implantation on the first single crystal substrate by the single crystal piezoelectric layer to sequentially divide the first single crystal substrate into a first layer, a damaged layer located above the first layer, and a second layer located above the damaged layer and the second layer located in contact with the single crystal piezoelectric layer;
forming a lower electrode layer on the single crystal piezoelectric layer;
forming a second substrate on the lower electrode layer by a bonding process;
splitting the first layer from the second layer at the damaged layer by heating process;
removing the second layer to expose the single crystal piezoelectric layer; and
forming an upper electrode layer on the single crystal piezoelectric layer.

2. The preparation method for the resonator according to claim 1, wherein removing the second layer to expose the single crystal piezoelectric layer comprises:
removing the second layer by trimming and wet-etching.

3. The preparation method for the resonator according to claim 1, wherein removing the second layer to expose the single crystal piezoelectric layer comprises:
removing the second layer by trimming and dry-etching.

4. The preparation method for the resonator according to claim 1, wherein the thickness ratio of the first layer to the second layer is greater than 1.

5. The preparation method for the resonator according to claim 1, wherein after forming the upper electrode layer on the single crystal piezoelectric layer, the method further comprises:
forming a first sacrificial layer on the upper electrode layer;
forming a first protective layer on the first sacrificial layer, wherein the first protective layer covers a top wall and a side wall of the first sacrificial layer; and
releasing the first sacrificial layer to form a first cavity located between the first protective layer and the upper electrode layer.

6. The preparation method for the resonator according to claim 5, wherein after releasing the first sacrificial layer to form the first cavity located between the first protective layer and the upper electrode layer, the method further comprises:
forming a back cavity penetrating the lower electrode layer on a side surface, away from the lower electrode layer, of the second substrate by etching.

7. The preparation method for the resonator according to claim 1, wherein forming the second substrate on the lower electrode layer by the bonding process comprises:
forming a second sacrificial layer on the lower electrode layer;
forming a first bonding layer on the second sacrificial layer;
forming a second bonding layer on the second substrate; and
bonding the first bonding layer and the second bonding layer to form the second substrate on the lower electrode layer.

8. The preparation method for the resonator according to claim 7, wherein after forming the upper electrode layer on the single crystal piezoelectric layer, the method further comprises:
forming a through hole penetrating the second sacrificial layer on a side surface, away from the lower electrode layer, of the upper electrode layer by etching;
forming a third sacrificial layer on the upper electrode layer in contact with the second sacrificial layer by the through hole;
forming a second protective layer on the third sacrificial layer, wherein the second protective layer covers a top wall and a side wall of the third sacrificial layer; and
sequentially releasing the third sacrificial layer and the second sacrificial layer to respectively form a second cavity located between the second protective layer and the upper electrode layer, and a third cavity located between the first bonding layer and the lower electrode layer.

9. The preparation method for the resonator according to claim 1, wherein an orthographic projection of the upper electrode layer and the lower electrode layer on the single crystal piezoelectric layer has an overlapping region and a non-overlapping region, and after forming the upper electrode layer on the single crystal piezoelectric layer, the method further comprises:
forming an extraction hole penetrating the lower electrode layer on a side surface, away from the lower electrode layer, of the single crystal piezoelectric layer by etching, wherein the extraction hole is located in the non-overlapping region of the lower electrode layer; and
forming an extraction electrode connected with the lower electrode layer by the extraction hole.

10. The preparation method for the resonator according to claim 1, wherein the first single crystal substrate is ion-implanted with single crystal ions for many times to form the damaged layer with a target thickness, as to reduce the lattice damage of the single crystal piezoelectric layer.

11. The preparation method for the resonator according to claim 10, wherein an ion displacement region of the first single crystal substrate is detected, and while the ion damage degree of the ion displacement region is greater than a threshold value, many times of the ion implantation is stopped.

12. The preparation method for the resonator according to claim 10, wherein a direction of ion implantation is consistent with a crystal axis direction of the single crystal piezoelectric layer.

13. The preparation method for the resonator according to claim 12, wherein after the many times of the ion implantation is stopped, the first layer, the damaged layer, and the second layer are thermally annealed, as to reduce the damage of an ion implantation layer.

14. The preparation method for the resonator according to claim 9, wherein before firstly forming the single crystal piezoelectric layer on the first single crystal substrate, the method further comprises etching a groove in the non-overlapping region preset on the first single crystal substrate; and
filling the groove with a fourth sacrificial layer, so that the height of the fourth sacrificial layer is higher than the surface of the first single crystal substrate.

15. The preparation method for the resonator according to claim 9, wherein before forming the second substrate on the lower electrode layer by the bonding process, further comprising:
forming a bonding layer between the overlapping region of the first single crystal substrate and the lower electrode layer.

16. The preparation method for the resonator according to claim 14, wherein after forming the upper electrode layer on the single crystal piezoelectric layer, further comprising:
releasing the fourth sacrificial layer to generate a resonator.

17. A resonator, wherein it is prepared by using the preparation method for the resonator according to claim 1.

18. The resonator according to claim 17, wherein a first sacrificial layer is formed on the upper electrode layer;
a first protective layer is formed on the first sacrificial layer, and the first protective layer covers a top wall and a side wall of the first sacrificial layer; and
the first sacrificial layer is released to form a first cavity located between the first protective layer and the upper electrode layer.

19. The resonator according to claim 18, wherein a second sacrificial layer is formed on the lower electrode layer;
a first bonding layer is formed on the second sacrificial layer;
a second bonding layer is formed on the second substrate; and
the first bonding layer and the second bonding layer are bonded to form the second substrate on the lower electrode layer.

20. A resonator, wherein it is prepared by using the preparation method for the resonator according to claim 14.
